(19) United States
(12) Patent Application Publication
(10) Pub. No.: US 2022/0013980 A1
(43) Pub. Date: Jan. 13, 2022

(54) OPTOELECTRONIC SEMICONDUCTOR LASER COMPONENT AND METHOD FOR PRODUCING AN OPTOELECTRONIC SEMICONDUCTOR LASER COMPONENT

(71) Applicant: OSRAM Opto Semiconductors GmbH, Regensburg (DE)

(72) Inventors: Harald König, Bernhardswald (DE); Alfred Lell, Maxhütte - Haidhof (DE)

(21) Appl. No.: 17/297,858

(22) PCT Filed: Nov. 18, 2019
(86) PCT No.: PCT/EP2019/081631

§ 371 Date: May 27, 2021

(30) Foreign Application Priority Data
Nov. 30, 2018 (DE) 10 2018 130 540.0

(51) Int. Cl. H01S 5/024; H01S 5/0225

(52) U.S. Cl. CPC H01S 5/02469; H01S 5/02476; H01S 5/0225

(57) ABSTRACT

An optoelectronic semiconductor laser component is specified. The optoelectronic semiconductor laser component comprises a semiconductor body with a first main surface, a second main surface, at least one active region formed between the first main surface and the second main surface, an output coupling surface extending from the first main surface to the second main surface, through which at least a part of the electromagnetic radiation is coupled out, a first heat sink arranged on the first main surface and a second heat sink arranged on the second main surface, and an optical protective element arranged downstream of the output coupling surface, for which the first heat sink and/or the second heat sink form a carrier. The outcoupling takes place in a main emission direction. Electrical contacting of the semiconductor body takes place by means of the first heat sink and the second heat sink. The first heat sink and/or the second heat sink comprise mounting surfaces on a side opposite the output coupling surface, on a side opposite the first main surface and/or on a side opposite the second main surface. A method for producing an optoelectronic semiconductor laser component is further specified.

### CROSS-REFERENCE TO RELATED APPLICATIONS

This patent application is a national stage entry from International Application No. PCT/EP2019/081631, filed on Nov. 18, 2019, published as International Publication No. WO 2020/109051 A1 on Jun. 4, 2020, and claims priority under 35 U.S.C. § 119 from German patent application 10 2018 130 540.0, filed Nov. 30, 2018, the entire contents of all of which are incorporated by reference herein.

### FIELD

An optoelectronic semiconductor laser component and a method for producing an optoelectronic semiconductor laser component are specified. The optoelectronic semiconductor laser component is configured in particular for generating coherent electromagnetic radiation, in particular light perceptible to the human eye.

### BACKGROUND

One task to be solved is to specify an optoelectronic semiconductor laser component that comprises improved efficiency and increased lifetime.

Another task to be solved is to specify a simplified method for producing an optoelectronic semiconductor laser component with an increased lifetime and efficiency.

### SUMMARY

According to at least one embodiment, the optoelectronic semiconductor laser component comprises a semiconductor body with a first main surface, a second main surface, and at least one active region formed between the first main surface and the second main surface. The semiconductor body is monolithic and preferably formed by epitaxial deposition. The active region is provided for emission of coherent electromagnetic radiation and preferably comprises a pn junction, a double heterostructure, a single quantum well (SQW) structure, or a multi-quantum well (MQW) structure for radiation generation. Further, the semiconductor body comprises an output coupling surface extending from the first main surface to the second main surface. The output coupling surface serves to couple out of the semiconductor body at least a portion of the electromagnetic radiation generated in the active region during operation of the optoelectronic semiconductor laser component. Further, the output coupling surface is in direct contact with a downstream body, in particular an optical protective element, a wavelength conversion element or a connection layer. Hereby, an improved heat dissipation can be achieved.

According to at least one embodiment of the optoelectronic semiconductor laser component, at least one region of the semiconductor body is based on a nitride compound semiconductor material.

“Based on nitride compound semiconductor material” means in the present context that the semiconductor layer sequence or at least a part thereof, particularly preferably at least the active zone and/or the growth substrate wafer, comprises or consists of a nitride compound semiconductor material, preferably AlₙGaₘI₁₋ₙ₋ₙN, wherein 0≤n≤1, 0≤m≤1 and n+m≤1. In this regard, this material need not necessarily comprise a mathematically exact composition according to the above formula. Rather, it may comprise, for example, one or more dopants as well as additional constituents. For the sake of simplicity, however, the above formula includes only the essential constituents of the crystal lattice (Al, Ga, In, N), even if these may be partially replaced and/or supplemented by small amounts of additional substances.

According to at least one embodiment, the optoelectronic semiconductor laser component comprises a first heat sink arranged on the first main surface and a second heat sink arranged on the second main surface. A heat sink is formed in particular from a material with good thermal conductivity. Due to an electrical resistance and optical absorptions, the semiconductor body heats up during operation. Excessive heating can lead to a disadvantageously reduced efficiency of the optoelectronic semiconductor laser component and ultimately to its complete destruction. A heat sink is used to dissipate heat from a device and thus lower an operating temperature or prevent excessive heating of the device. The first and second heat sinks are preferably directly adjacent to the first and second main surfaces of the semiconductor body, and thus allow very good heat transfer from the semiconductor body to the first and second heat sinks. The first and second heat sinks are further preferably formed with a metal or a ceramic material.

In particular, the first heat sink and the second heat sink each comprise a recess on the side opposite the output coupling surface facing the semiconductor body, which together form a first cavity. Such a first cavity is used, for example, to avoid solder short circuits when attaching the first and second heat sinks by means of a soldering process.

For example, the first and second heat sinks each comprise a further recess on the side facing the output coupling surface, which together form a second cavity. The second cavity is arranged on the side of the first and second heat sinks facing the semiconductor body. The second cavity may, for example, be filled with a wavelength conversion material and preferably comprises a flank angle corresponding to the divergence of the electromagnetic radiation exiting the output coupling surface.

For example, there is a spacer between the first and second heat sinks that is electrically insulated. The thickness of the spacer corresponds to the thickness of the semiconductor body, thus enabling precise alignment of the first and second heat sinks on the semiconductor body.

According to at least one embodiment, the optoelectronic semiconductor laser component comprises an optical protective element located downstream of the output coupling surface. The first heat sink and/or the second heat sink form a mechanical carrier for the optical protective element. The optical protective element serves to encapsulate the semiconductor body and thus to protect it from external environmental influences. For example, external moisture ingress or mechanical damage to the semiconductor body is detrimental to its operation. The first and/or the second heat sink form a carrier for the optical protective element in such a way that the optical protective element is mechanically firmly connected with the first and/or the second heat sink. In particular, the optical protective element is designed to be transmissive to the electromagnetic radiation generated in the active region during operation. The optical protective element is designed, for example, as a layer or layer stack deposited directly on the output coupling surface and or the first and/or the second heat sink. Further, the optical protective element may be a wavelength conversion element and may be configured to convert electromagnetic radiation.

According to at least one embodiment of the optoelectronic semiconductor laser component, the emission of electromagnetic radiation occurs in a main emission direction. The emitted electromagnetic radiation may comprise a divergence in particular in the main emission direction.

According to at least one embodiment of the optoelectronic semiconductor laser component, electrical contacting of the semiconductor body takes place by means of the first heat sink and the second heat sink. For example, the first heat sink forms a cathode and the second heat sink forms an anode. For this purpose, the first heat sink and the second heat sink comprise an electrical conductivity at least in regions and thus form an electrically conductive path to the semiconductor body.

According to at least one embodiment of the optoelectronic semiconductor laser component, the first heat sink and/or the second heat sink comprise mounting surfaces on the side opposite the output coupling surface, on the side opposite the first main surface and/or on a side opposite the second main surface. Mounting surfaces serve in particular for mechanical and electrical mounting of the optoelectronic semiconductor laser component on a substrate provided therefor. A mounting surface is in particular planar and preferably comprises an electrical conductivity suitable for electrical contacting of the semiconductor laser component.

According to at least one embodiment, the optoelectronic semiconductor laser component comprises
a semiconductor body with
   a first main surface,
   a second main surface,
   at least one active region formed between the first main surface and the second main surface and intended to emit coherent electromagnetic radiation,
   an output coupling surface extending from the first main surface to the second main surface, through which at least a portion of the electromagnetic radiation is coupled out,
a first heat sink disposed on the first main surface and a second heat sink disposed on the second main surface, and
an optical protective element arranged downstream of the output coupling surface, for which the first heat sink and/or the second heat sink form a carrier, wherein
the emission takes place in a main emission direction,
electrical contacting of the semiconductor body is effected by means of the first heat sink and the second heat sink, and
the first heat sink and/or the second heat sink comprise mounting surfaces on a side opposite the output coupling surface, on a side opposite the first main surface and/or on a side opposite the second main surface.

An optoelectronic semiconductor laser component described herein is based on the following considerations, inter alia: when an optoelectronic semiconductor laser component is operated with large currents to generate a high optical output power for a long time, a large waste heat may be generated. To avoid excessive heating of the component, the waste heat is dissipated from the optoelectronic semiconductor laser component. In particular, when arranging a plurality of laterally spaced active regions, for example in a laser bar, the removal of the resulting waste heat can limit the maximum achievable optical output power. Laser bars comprise a plurality of laterally adjacent active regions and can be used to generate high optical output powers. Furthermore, a semiconductor body often reacts in an undesirable manner with external environmental influences. External environmental influences, such as moisture or mechanical stress, can damage a semiconductor body.

The optoelectronic semiconductor laser component described here makes use, inter alia, of the idea of achieving improved dissipation of waste heat generated in the semiconductor body by means of two heat sinks that completely cover the semiconductor body from two opposite sides. Thus, for example, a higher density of active regions and an increased optical output power can be achieved in a laser bar. Furthermore, an optical protective element, for example in the form of a dielectric encapsulation on the output coupling surface, prevents degradation due to environmental influences. Further, the optical protective element may also be configured for improved heat dissipation from the semiconductor body and the output coupling surface.

According to at least one embodiment of the optoelectronic semiconductor laser component, the semiconductor body comprises a plurality of active regions arranged laterally spaced apart. The semiconductor body preferably comprises 2 to 100, particularly preferably 2 to 10 or 10 to 100 active regions. Such an arrangement is referred to as a laser bar.

The main emission directions of all active regions are parallel to each other. The active regions are arranged at a distance from one another in a direction transverse to the main emission direction and parallel to the main extension direction of the semiconductor body. The arranging of multiple active regions in a monolithically designed semiconductor body can be used for power scaling.

According to at least one embodiment of the optoelectronic semiconductor laser component, the lateral distance of the active regions from one another decreases from the center of the semiconductor body outwardly. This advantageously results in a particularly uniform heat dissipation of the semiconductor body.

According to at least one embodiment of the optoelectronic semiconductor laser component, the lateral distance of the active regions from one another increases outwardly starting from the center of the semiconductor body. As a result, the temperature of the active regions arranged in the center of the semiconductor body may increase, which may help to improve the efficiency in case of suitable semiconductor material systems.

According to at least one embodiment of the optoelectronic semiconductor laser component, the optical protective element is in direct contact with the output coupling surface, the first heat sink and/or the second heat sink. This means that the optical protective element is in direct contact with at least one of the three mentioned components (first heat sink, second heat sink, output coupling surface), but it can also be in direct contact with two components or even with all three components. The output coupling surface is completely covered by the optical protective element. The output coupling surface is thus protected from the effects of moisture and mechanical damage from the outside. The optical protective element thereby preferably comprises a thickness of at least 5 nm to 1000 nm, particularly preferably 10 nm to 200 nm.

According to at least one embodiment of the optoelectronic semiconductor laser component, the optical protective element is formed with a dielectric material. For example, the optical protective element is formed with one or more of the following materials: SiO₂, Al₂O₃, ZrO₂, HfO₂, TiO₂, Ta₂O₅, Si₃N₄, Nb₂O₅, Y₂O₃, Ho₂O₃, CeO₂, Lu₂O₃, V₂O₅, HfZrO, MgO, TaC, ZnO, CuO, In₂O₃, Yb₂O₃, Sm₂O₃, Nd₂O₃, Sc₂O₃, B₂O₃, Er₂O₃, Dy₂O₃, Tm₂O₃, SrTiO₃, BaTiO₃, PbTiO₃, PbZrO₃, Ga₂O₃, HfAlO, HfTaO, SiC, DLC (Diamond Like Carbon), Diamant, AlN, AlGaN.

For example, the optical protective element comprises a multilayer structure containing several materials of the previously mentioned list. In this way, an advantageously dense structure can be achieved, which comprises a very high resistance to external moisture ingress. The materials of the different layers can also be applied, for example, by means of different methods. Preferably, the optical protective element comprises a multilayer structure with alternating layers, wherein different materials are used in each case, each with different lattice constants from one another, so as to produce the densest possible encapsulation layer.

If the optical protective element is formed with a material having a very high thermal conductivity, such as SiC, DLC, AlN or AlGaN, it can advantageously also perform a heat dissipating function. The heat-dissipating layer can, for example, result in even better heat dissipation from the semiconductor body due to the material connection with the output coupling surface. Heat dissipation from the particularly sensitive output coupling surface can thus be improved.

According to at least one embodiment of the optoelectronic semiconductor laser component, the optical protective element is formed with a glass or a sapphire. A glass or a sapphire is characterized in particular by a high radiation transmission and a high mechanical stability. Further, such an optical protective element, for example a glass or sapphire plate, may comprise an optical coating layer on the side facing the output coupling surface and/or on the side facing away from the output coupling surface. A coating layer is, for example, an anti-reflective layer that advantageously increases a transmittance of an electromagnetic radiation. The optical protective element may further advantageously comprise a thermally conductive layer on the side facing the output coupling surface. A heat-conducting layer can advantageously increase a heat dissipation from the output coupling surface and a heat input into the first and/or the second heat sink. This can result in particularly good heat dissipation from the semiconductor body and, in particular, from the output coupling surface of the semiconductor body.

According to at least one embodiment of the optoelectronic semiconductor laser component, the optical protective element is materially connected to the first heat sink and/or the second heat sink by means of a connection layer. The connection layer may be, for example, an adhesive or solder layer and may comprise silicone or epoxy resin. The connection layer connects the optical protective element to the first and/or the second heat sink in a mechanically stable manner. As explained above, the optical protective element may be in direct contact with the first heat sink and/or the second heat sink and/or the output coupling surface.

According to at least one embodiment of the optoelectronic semiconductor laser component, the connection layer completely covers the output coupling surface. A complete covering of the output coupling surface advantageously results in a good protection against external environmental influences. Furthermore, complete coverage can ensure particularly good heat dissipation.

According to at least one embodiment of the optoelectronic semiconductor laser component, the protective element comprises the shape of a lens. A lens is transparent to an electromagnetic radiation and is configured to influence the propagation characteristics of an electromagnetic radiation as it passes through the lens. For example, a lens may be used to focus or collimate radiation. In an embodiment of the optical protective element in the form of a lens, a further external lens can advantageously be dispensed with.

According to at least one embodiment of the optoelectronic semiconductor laser component, the optical protective element is provided for collimation of electromagnetic radiation exiting the output coupling surface during operation of the optoelectronic semiconductor laser component in at least one axis transverse to the main emission direction. On the one hand, a collimation serves to guide the electromagnetic radiation in a predetermined manner. On the other hand, collimation of the electromagnetic radiation can also advantageously reduce a burn-in of particles from the environment on the output coupling surface. Such particles, due to an interaction with an electromagnetic field, migrate to the location of highest intensity. As a result, particles preferentially collect on the output coupling surface, reduce its permeability as burn-in and finally lead to a defect (COD, catastrophic optical damage). A divergent beam is disadvantageous for burn-in. The widening and collimation of the beam reduce the electromagnetic field strength at the surface of the optical protective element. Reduced field strength decreases the tendency of particles to migrate toward the output coupling surface. Thus, an expanded and collimated beam advantageously reduces a burn-in of particles on the output coupling surface.

According to at least one embodiment of the optoelectronic semiconductor laser component, the optical protective element comprises a wavelength conversion element. A wavelength conversion element is configured to convert electromagnetic radiation of a first wavelength to electromagnetic radiation of a second wavelength. In particular, the converted electromagnetic radiation of the second wavelength comprises a broader spectral distribution than the exciting electromagnetic radiation of the first wavelength. Further, it is also possible for the second wavelength electromagnetic radiation to comprise a spectral width that is equal to, similar to, or less than the spectral width of the first wavelength electromagnetic radiation.

For example, a wavelength conversion element comprises a radiation-transmissive matrix with particles of a wavelength conversion material or a ceramic converter material embedded therein, such as in the form of a wafer. A wavelength conversion element can be used, for example, to generate white light. The wavelength conversion element may be located downstream of the optical protective element, arranged between the optical protective element and the output coupling surface, or fully embedded in the optical protective element. If the wavelength conversion element is embedded in the optical protective element, the optical protective element surrounds the wavelength conversion element and thus ensures sufficiently good encapsulation and protection of the wavelength conversion element from external environmental influences. An optical filter element may be arranged between the wavelength conversion element and the optical protective element. For example, the optical filter element may be a dichromatic filter configured to reflect radiation of a particular electromagnetic wavelength and transmit radiation of an electromagnetic wavelength different therefrom. For example, the dichromatic filter is configured to reflect radiation converted by the wavelength conversion element and to be transmissive to radiation coupled out of the semiconductor body.

According to at least one embodiment of the optoelectronic semiconductor laser component, the wavelength conversion element is an optical crystal, for example, a laser crystal such as titanium sapphire or Nd:YAG. An optical crystal may be optically pumped by means of coherent radiation of a first wavelength exiting the output coupling surface, thereby being excited to emit coherent radiation of a second wavelength, wherein the second wavelength is different from the first wavelength.

According to at least one embodiment of the optoelectronic semiconductor laser component, the first heat sink and/or the second heat sink is formed with at least one of the following materials: Copper, Copper-Steel, Copper-Tungsten, Gold, Copper-Molybdenum, Copper-Diamond, Aluminum Nitride, Silicon Carbide, Boron Nitride, DBC (Direct Bonded Copper), Diamond or DLC. The aforementioned materials comprise high thermal conductivity and are also electrically conductive. Thus, the first and second heat sinks can efficiently dissipate heat from the semiconductor body and also form the electrical connection for the semiconductor body.

According to at least one embodiment of the optoelectronic semiconductor laser component, the first heat sink and/or the second heat sink comprise an electrically conductive contact structure. Provided that the electrical conductivity of the heat sinks as solid material is not yet sufficient, a sufficiently high electrical conductivity can be produced by an electrically conductive contact structure. An electrically conductive contact structure is formed with an electrically highly conductive material such as copper. The contact structure may extend inside a heat sink or be attached to one of its outer sides.

According to at least one embodiment of the optoelectronic semiconductor laser component, the first heat sink and the second heat sink protrude the optical protective element in a direction parallel to the main emission direction. This provides a mechanical protective effect for the optical protective element. Further advantageously, an adjustment for the optical protective element with respect to the first and second heat sinks can thus be created in advance. The first and second heat sinks may provide a lateral boundary for the optical protective element in a plane transverse to the main emission direction. With other words, the first heat sink and the second heat sink can form a lateral guide for the optical protective element. Thus, mounting the optical protective element on the first and second heat sinks is facilitated. Furthermore, the mechanical stability of the optical protective element can thus be improved.

According to at least one embodiment of the optoelectronic semiconductor laser component, the semiconductor body comprises side surfaces extending transversely or perpendicularly to the output coupling surface. At least one, preferably all, of these side surfaces are not covered by either the first heat sink or the second heat sink. With other words, the side surfaces are free of the material of the heat sinks.

According to at least one embodiment of the optoelectronic semiconductor laser component, a compensation layer is arranged between the semiconductor body and the first heat sink and/or between the semiconductor body and the second heat sink. In particular, a compensation layer can be a layer that serves to compensate for different coefficients of thermal expansion of the semiconductor body and the first or the second heat sink. The coefficient of thermal expansion of the compensation layer thus lies between the coefficient of thermal expansion of the semiconductor body and the coefficients of thermal expansion of the first and second heat sinks. The compensation layer preferably comprises high thermal and electrical conductivity. The compensation layer can contact the semiconductor body thermally and electrically with the first and/or second heat sinks. A brazing solder may be arranged between the compensation layer and the semiconductor body. Suitable brazing alloys include, inter alia, an alloy of gold and tin. A brazing alloy is characterized in particular by high mechanical stability and reliability.

According to at least one embodiment of the optoelectronic semiconductor laser component, the first heat sink and the second heat sink protrude the at least one compensation layer in the main emission direction, and the output coupling surface protrudes the at least one compensation layer in the main emission direction. This serves to provide unobstructed emission of the coherent divergent radiation, since shading of the output coupling surface by the compensation layer can be avoided. Furthermore, the first and second heat sinks protrude the output coupling surface, which protects the output coupling surface from mechanical damage, for example when the optical protective element is placed on top.

According to at least one embodiment of the optoelectronic semiconductor laser component, the at least one compensation layer is formed with at least one of the following materials: Copper, Molybdenum, Diamond, Tungsten, DLC or SiC. In particular, the compensation layer is formed with an electrically conductive material and/or comprises an electrically conductive layer. If the compensation layer itself does not comprise sufficient electrical conductivity, the electrical contacting of the semiconductor body may be carried out with the electrically conductive layer. For example, the electrically conductive layer is formed with at least one of the following materials: Gold, tin, copper, silver, indium.

Furthermore, a method for producing an optoelectronic semiconductor laser component is specified. In particular, the method can be used to fabricate an optoelectronic semiconductor laser component described herein. That is, all features disclosed for the optoelectronic semiconductor laser component are also disclosed for the method, and vice versa.

According to at least one embodiment of a method for producing an optoelectronic semiconductor laser component, the method comprises the following steps: Providing a semiconductor body, with a first main surface, a second main surface, and at least one active region formed between the first main surface and the second main surface and provided for emitting coherent electromagnetic radiation. Further, the semiconductor body comprises an output coupling surface extending from the first main surface to the second main surface through which at least a portion of the electromagnetic radiation is coupled out.

According to at least one embodiment of the method for producing an optoelectronic semiconductor laser component, arranging a first heat sink on the first main surface and arranging a second heat sink on the second main surface are performed. The arranging of the first and the second heat sinks on the semiconductor body is performed, for example, by means of a soldering process.

According to at least one embodiment of the method for producing an optoelectronic semiconductor laser component, arranging an optical protective element on the first heat sink and the second heat sink is performed such that the optical protective element is arranged downstream of the output coupling surface.

According to at least one embodiment of the method for producing an optoelectronic semiconductor laser component, the optical protective element is formed with a dielectric material and is produced by one or a combination of the following methods:

ALD (Atomic Layer Deposition), CVD (Chemical Vapor Deposition), IBD (Ion Beam Deposition), IP (Ion Plating), sputtering, vapor deposition, MVD (Molecular Vapor Deposition). By means of an ALD method, it is advantageously possible to produce particularly dense layers that offer good protection against moisture. The optical protective element can also be manufactured using a multilayer structure and a combination of the previously mentioned methods. Alternatively, the optical protective element can also be made from a pre-cut glass or sapphire plate, which is arranged on one of the first and second heat sinks by means of a connection layer.

According to at least one embodiment of the method for producing an optoelectronic semiconductor laser component, the optical protective element is formed with a glass and is arranged by means of reflow in a second cavity of the first heat sink and the second heat sink. For example, a liquid glass material may be brought into a second cavity of the first and second heat sinks such that the optical protective element is disposed downstream of the output coupling surface and completely encapsulates the semiconductor body on its side facing the output coupling surface. If a glass is attached to the semiconductor body by means of fusing, this results in an advantageously particularly tight encapsulation and good protection against external environmental influences for the semiconductor body.

### BRIEF DESCRIPTION OF THE DRAWINGS

Further advantages and advantageous embodiments and further embodiments of the optoelectronic semiconductor component result from the following exemplary embodiments shown in connection with the figures.

Showing in:

FIGS. 1A and 1B schematic representations of an optoelectronic semiconductor laser component described herein according to a first exemplary embodiment in a sectional view (FIG. 1A) and a perspective view (FIG. 1B),

FIGS. 2A and 2B schematic representations of an optoelectronic semiconductor laser component described herein according to a second exemplary embodiment in a sectional view (FIG. 2A) and a perspective view (FIG. 2B),

FIGS. 3A and 3B schematic representations of an optoelectronic semiconductor laser component described herein according to a third exemplary embodiment in a sectional view (FIG. 3A) and a perspective view (FIG. 3B),

FIGS. 4A and 4B schematic representations of an optoelectronic semiconductor laser component described herein according to a fourth exemplary embodiment in a sectional view (FIG. 4A) and a perspective view (FIG. 4B),

FIG. 5 a schematic sectional view of an optoelectronic semiconductor laser component described herein according to a fifth exemplary embodiment,

FIG. 6 a schematic sectional view of an optoelectronic semiconductor laser component described herein according to a sixth exemplary embodiment,

FIG. 7 a schematic sectional view of an optoelectronic semiconductor laser component described herein according to a seventh exemplary embodiment,

FIG. 8 a schematic sectional view of an optoelectronic semiconductor laser component described herein according to an eighth exemplary embodiment,

FIG. 9 a schematic sectional view of an optoelectronic semiconductor laser component described herein according to a ninth exemplary embodiment,

FIG. 10 a schematic sectional view of an optoelectronic semiconductor laser component described herein according to a tenth exemplary embodiment,

FIG. 11 a schematic sectional view of an optoelectronic semiconductor laser component described herein according to an eleventh exemplary embodiment,

FIG. 12 a schematic sectional view of an optoelectronic semiconductor laser component described herein according to a twelfth exemplary embodiment,

FIG. 13 a schematic sectional view of an optoelectronic semiconductor laser component described herein according to a 13th exemplary embodiment,

FIG. 14 a schematic sectional view of an optoelectronic semiconductor laser component described herein according to a 14th exemplary embodiment,

FIGS. 15 to 17 schematic sectional views of an optoelectronic semiconductor laser component described herein according to a 15th exemplary embodiment, each with different embodiments of a wavelength conversion layer,

FIG. 18 a schematic sectional view of an optoelectronic semiconductor laser component described herein according to a 16th exemplary embodiment,

FIGS. 19 to 21 schematic sectional views of an optoelectronic semiconductor laser component described herein according to a 17th exemplary embodiment, each with different embodiments of a connection layer and an optical protective element,

FIGS. 22A and 22B schematic sectional views (FIG. 22A) and perspective views (FIG. 22B) of an optoelectronic semiconductor laser component described herein according to an 18th exemplary embodiment,

FIGS. 23 to 25 schematic sectional views of an optoelectronic semiconductor laser component described herein according to a 19th exemplary embodiment, each with different embodiments of electrical contacting,

FIG. 26 schematic sectional views of a plurality of optoelectronic semiconductor laser components described herein on a substrate according to a 20th exemplary embodiment,

FIGS. 27A and 27B schematic representations of an optoelectronic semiconductor laser component described herein according to a 21st exemplary embodiment in a sectional view (FIG. 27A) and a perspective view (FIG. 27B),

FIG. 28 a schematic sectional view of an optoelectronic semiconductor laser component described herein according to a 22nd exemplary embodiment,

FIG. 29 a schematic sectional view of an optoelectronic semiconductor laser component described herein according to a 23rd exemplary embodiment, and

FIG. 30 a schematic sectional view of an optoelectronic semiconductor laser component described herein according to a 24th exemplary embodiment.

### DETAILED DESCRIPTION

Identical, similar, or similar-acting elements are indicated in the figures with the same reference signs. The figures and the proportions of the elements shown in the figures with respect to each other are not to be regarded as to scale. Rather, individual elements may be shown exaggeratedly large for better representability and/or for better comprehensibility.

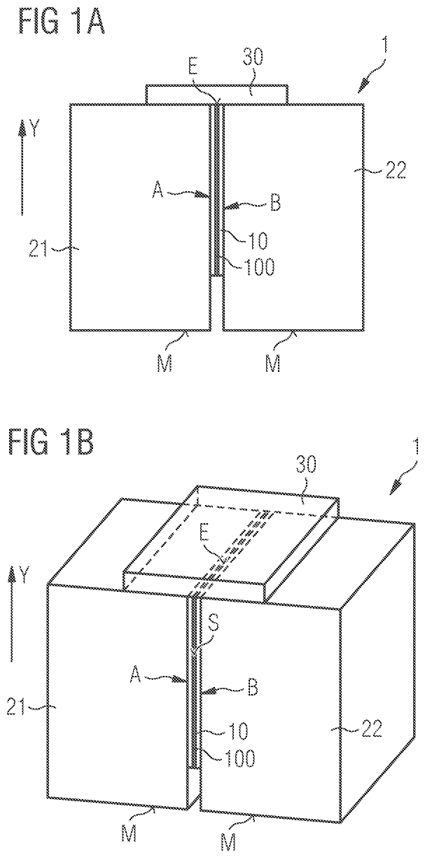

FIGS. 1A and 1B show schematic representations of an optoelectronic semiconductor laser component 1 described herein according to a first exemplary embodiment. FIG. 1A shows a sectional view of an optoelectronic semiconductor laser component 1. The optoelectronic semiconductor laser component 1 comprises a semiconductor body 10 with a first main surface A, a second main surface B and an active region 100 formed between the first main surface A and the second main surface B. The active region 100 is configured to emit coherent electromagnetic radiation and preferably comprises a pn junction. In particular, the semiconductor body 10 comprises a plurality of active regions 100 that are laterally spaced apart and arranged side by side. The optoelectronic semiconductor component 1 may thus constitute a laser bar. An output coupling surface E extends from the first main surface A to the second main surface B, through which at least a portion of the electromagnetic radiation generated in the active region 100 during operation of the optoelectronic semiconductor laser component 1 is coupled out. The electromagnetic radiation is emitted in a main emission direction Y, which is parallel to a normal vector of the output coupling surface E. The output coupling surface (E) is in direct contact with the optical protective element (30).

A first heat sink 21 is arranged on the first main surface A. A second heat sink 22 is arranged on the second main surface B. The first heat sink 21 and the second heat sink 22 are formed with a material that comprises a high thermal conductivity. For example, the first and second heat sinks 21, 22 are formed with copper, an alloy of copper and steel, an alloy of copper and tungsten, gold, an alloy of copper and molybdenum, or a copper-diamond composite. These materials advantageously have high thermal conductivity and also high electrical conductivity.

The electrical contacting of the optoelectronic semiconductor laser component 1 takes place via the first heat sink 21 and the second heat sink 22. For example, the first heat sink 21 acts as an anode and the second heat sink 22 acts as a cathode. The first heat sink 21 and the second heat sink 22 each comprise a mounting surface M on their side opposite the output coupling surface E. By means of the mounting surface M, the optoelectronic semiconductor laser component 1 can be mounted on a carrier provided for this purpose, for example a contact region 51 of a substrate 2.

Downstream of the output coupling surface E is an optical protective element 30. The optical protective element 30 completely covers the output coupling surface E and extends in the lateral direction as far as the first and second heat sinks 21, 22. The optical protective element 30 is connected to the first and second heat sinks 21, 22 by a material bond. The optical protective element 30 is formed with a dielectric material and is made transmissive, preferably transparent, to electromagnetic radiation exiting the output coupling surface E of the semiconductor body 10 during operation. For example, the optical protective element 30 is formed with one or a combination of the following materials: SiO₂, Al₂O₃, ZrO₂, HfO₂, TiO₂, Ta₂O₅, Si₃N₄, Nb₂O₅, Y₂O₃, Ho₂O₃, CeO₂, Lu₂O₃, V₂O₅, HfZrO, MgO, TaC, ZnO, CuO, In₂O₃, Yb₂O₃, Sm₂O₃, Nd₂O₃, Sc₂O₃, B₂O₃, Er₂O₃, Dy₂O₃, Tm₂O₃, SrTiO₃, BaTiO₃, PbTiO₃, PbZrO₃, Ga₂O₃, HfAlO, HfTaO.

The optical protective element 30 serves to encapsulate the semiconductor body 10. The materials of the semiconductor body may be damaged by external environmental influences, such as moisture. In order to ensure sufficient impermeability to moisture and other external environmental influences, the optical protective element 30 comprises a thickness of at least 5 nm to 1000 nm, preferably from 10 nm to 200 nm. Advantageously, a further hermetic housing for the entire optoelectronic semiconductor laser component 1 can thus be dispensed with. The optical protective element 30 is deposited on the first and second heat sinks 21, 22 and the semiconductor body 10 by, for example, one of the following methods or a combination of the following methods: atomic layer deposition (ALD), chemical vapor deposition (CVD), ion beam deposition (IBD), ion plating (IP), sputtering, vapor deposition or molecular vapor deposition (MVD).

For example, the optical protective element 30 is formed with a multilayer structure. Different layers, are formed with different materials respectively, and produced with one or more of the methods mentioned. In this way, a particularly dense optical protective element 30 can be advantageously produced, which offers a high resistance to external environmental influences.

FIG. 1B shows a perspective view of the optoelectronic semiconductor laser component 1 shown in FIG. 1A according to the first exemplary embodiment. In the perspective view, a side surface S of the semiconductor body 10 is shown. The side surface S extends transversely to the first and second main surfaces of the semiconductor body 10. The side surface S is not covered by the first heat sink 21 and the second heat sink 22.

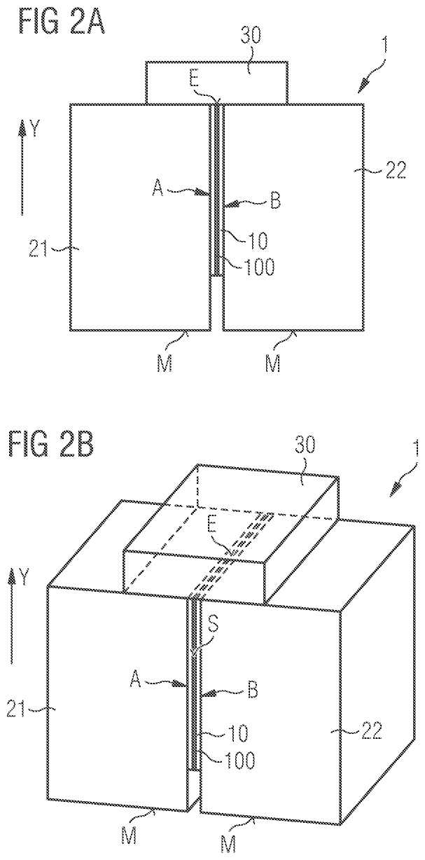

FIGS. 2A and 2B show schematic representations of an optoelectronic semiconductor laser component 1 described herein according to a second exemplary embodiment. FIG. 2A shows a sectional view of an optoelectronic semiconductor laser component 1. The second exemplary embodiment corresponds in essential parts to the first exemplary embodiment according to FIGS. 1A and 1B. Unlike the first exemplary embodiment shown in FIG. 1A, the second exemplary embodiment shown in FIG. 2A comprises a differently designed optical protective element 30. The optical protective element 30 shown here additionally serves to dissipate heat from the output coupling surface E of the semiconductor body 10, and is formed with one or more of the following materials: Silicon Carbide, DLC, AlN or AlGaN. These materials serve, on the one hand, to encapsulate the semiconductor body and, on the other hand, comprise a particularly high thermal conductivity.

The thickness, i.e. the extent in the direction of the main emission direction Y of the optical protective element 30 is at least 100 nm to 1000 μm to ensure sufficient heat dissipation. The output coupling surface E is in direct contact with the optical protective element 30, the first heat sink 21 and the second heat sink 22, thus forming a thermally conductive path between the output coupling surface E and the first and second heat sinks 21, 22. The sensitive output coupling surface E of the semiconductor body 10 can thus advantageously be particularly well cooled. Effective heat dissipation of the output coupling surface E contributes to a particularly long lifetime of the optoelectronic semiconductor laser component 1.

FIG. 2B shows a perspective view of the optoelectronic semiconductor laser component 1 shown in FIG. 2A according to the second exemplary embodiment. In the perspective view, a side surface S of the semiconductor body 10 is shown. The side surface S extends transversely to the first and second main surfaces of the semiconductor body 10. The side surface S is not covered by the first heat sink 21 and the second heat sink 22.

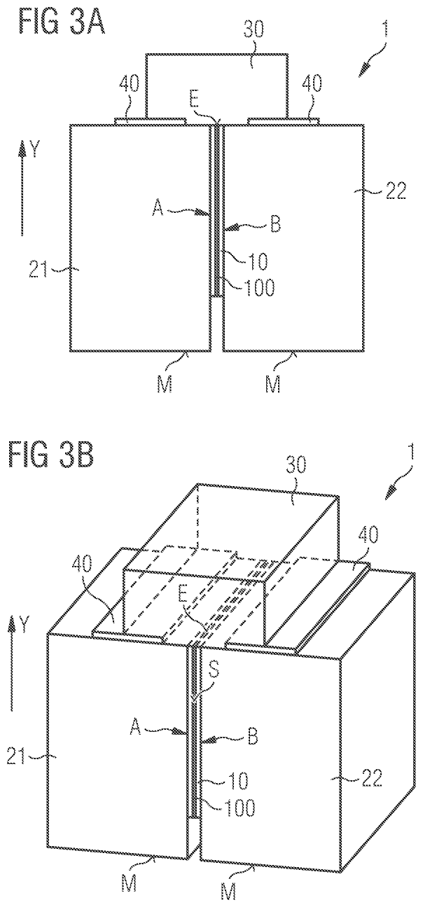

FIGS. 3A and 3B show schematic representations of an optoelectronic semiconductor laser component 1 described herein according to a third exemplary embodiment. The third exemplary embodiment corresponds in essential parts to the second exemplary embodiment according to FIGS. 2A and 2B. FIG. 3A shows a sectional view of an optoelectronic semiconductor laser component 1. In contrast to the optoelectronic semiconductor laser component 1 shown in FIG. 2A, the optoelectronic semiconductor laser component 1 shown in FIG. 3A comprises a different optical protective element 30. The optical protective element 30 is designed as a glass or sapphire platelet, which is connected to the first heat sink 21 and the second heat sink 22 by means of a connection layer 40. Furthermore, the optical protective element 30 is designed to be transmissive or transparent to the electromagnetic radiation exiting from the output coupling surface E.

The connection layer 40 may be formed with a glass solder, a metallic solder material, or with an adhesive, for example an epoxy or silicone. The optical protective element 30 may include an optical coating layer on its side facing the output coupling surface E.

Furthermore, a coating layer may be provided on the side of the optical protective element 30 facing away from the output coupling surface. A coating layer is, for example, an anti-reflective layer which advantageously enables particularly efficient passage of electromagnetic radiation through the optical protective element 30 and reduces or avoids undesired reflections. Furthermore, the optical protective element can comprise a highly thermally conductive layer on its side facing the output coupling surface E. This highly thermally conductive layer can be in direct contact with the output coupling surface E to dissipate heat from the semiconductor body 10.

FIG. 3B shows a perspective view of the optoelectronic semiconductor laser component 1 shown in FIG. 3A according to the third exemplary embodiment. In the perspective view, a side surface S of the semiconductor body 10 is shown. The side surface S extends transversely to the first and second main surfaces of the semiconductor body 10. The side surface S is not covered by the first heat sink 21 and the second heat sink 22.

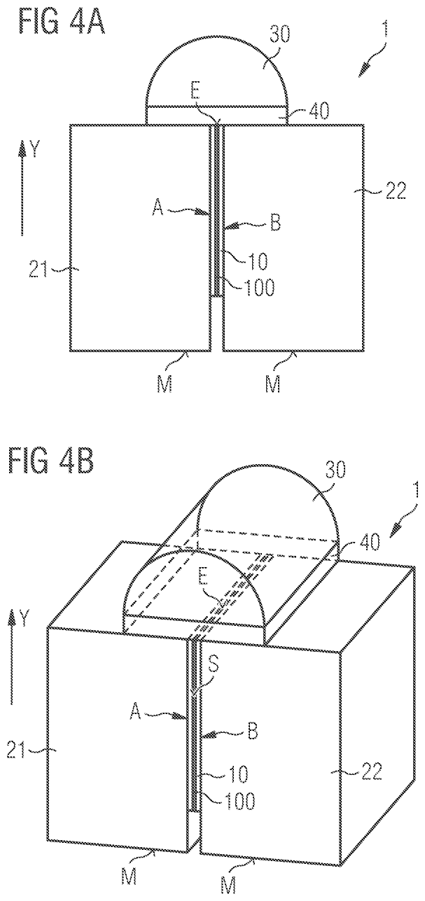

FIGS. 4A and 4B show schematic representations of an optoelectronic semiconductor component described herein according to a fourth exemplary embodiment. The fourth exemplary embodiment is substantially the same as the third exemplary embodiment shown in FIGS. 3A and 3B. FIG. 4A shows a sectional view of an optoelectronic semiconductor laser component 1. Unlike the optoelectronic semiconductor laser component 1 shown in FIG. 3A, the optical protective element 30 in the exemplary embodiment shown in FIG. 4A comprises a lens shape. The optical protective element 30 is mounted on the first and second heat sinks 21, 22 by means of a connection layer 40. The connection layer 40 is formed with a siloxane or a silicone adhesive. The connection layer 40 is made sufficiently stable and radiation-transmissive with respect to electromagnetic radiation exiting from the output coupling surface E. The output coupling surface (E) is in direct contact with the connection layer (40).

The connection layer 40 completely covers the output coupling surface E and protects the output coupling surface from external environmental influences. The connection layer 40 is in direct contact with the output coupling surface (E) and the first and second heat sinks 21, 22. The optical protective element 30 in the form of a lens is configured to collimate the coherent electromagnetic radiation exiting from the output coupling surface E in at least one of the spatial directions transverse to the main emission direction Y. The collimation homogenizes the intensity of the electromagnetic radiation in a direction transverse to its propagation direction. By an expansion and a collimation of the electromagnetic radiation, a burning-in of dirt particles from the environment on the output coupling surface E can be advantageously reduced or avoided.

FIG. 4B shows a perspective view of the optoelectronic semiconductor laser component 1 shown in FIG. 4A according to the fourth exemplary embodiment. In the perspective view, a side surface S of the semiconductor body 10 is shown. The side surface S extends transversely to the first and second main surfaces of the semiconductor body 10. The side surface S is not covered by the first heat sink 21 and the second heat sink 22.

FIG. 5 shows a schematic sectional view of an optoelectronic semiconductor laser component 1 described herein according to a fifth exemplary embodiment. The fifth exemplary embodiment corresponds in essential parts to the fourth exemplary embodiment according to FIGS. 4A and 4B. In contrast to the exemplary embodiment shown in FIG. 4A, the exemplary embodiment of an optoelectronic semiconductor laser component shown in FIG. 5 comprises differently designed first and second heat sinks 21, 22. The first heat sink 21 and the second heat sink 22 each comprise cutouts on their side facing the mounting surface M, which form a first cavity 81. This first cavity 81 increases the distance between the first heat sink 21 and the second heat sink 22 at their mounting surface M. An increased distance between the mounting surface M makes it easier to mount the optoelectronic semiconductor laser component 1 on a contact region 51 provided for this purpose by means of a solder connection. A smaller spacing of the mounting surfaces M disadvantageously requires greater accuracy during mounting and increases the risk of a solder short circuit between the first heat sink 21 and the second heat sink 22.

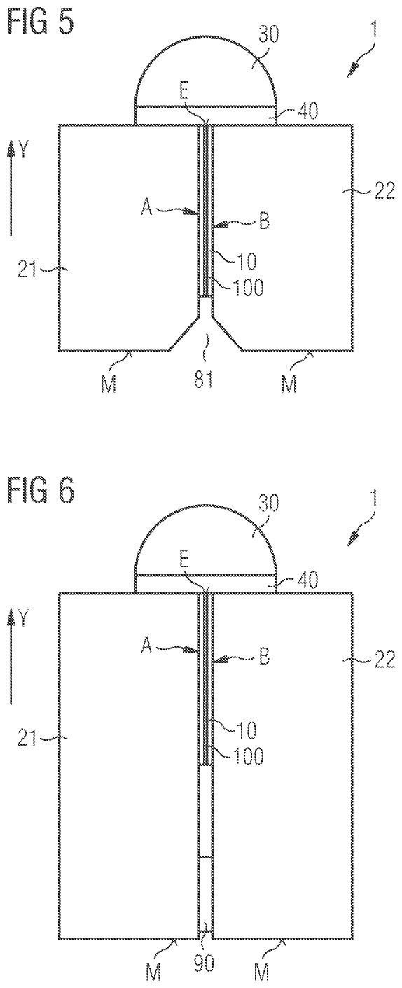

FIG. 6 shows a schematic sectional view of an optoelectronic semiconductor laser component 1 described herein according to a sixth exemplary embodiment. The sixth exemplary embodiment corresponds in essential parts to the fifth exemplary embodiment according to FIG. 5. In contrast to the exemplary embodiment shown in FIG. 5, the exemplary embodiment of an optoelectronic semiconductor laser component 1 shown in FIG. 6 comprises a spacer 90 between the first heat sink 21 and the second heat sink 22. The spacer 90 serves to mechanically stabilize the optoelectronic semiconductor laser component 1. The spacer 90 is arranged on the side of the heat sink 21, 22 facing the mounting surface and serves to improve alignment and mechanically stabilize the optoelectronic semiconductor laser component 1. Furthermore, the spacer 90 is electrically insulating to prevent a short circuit between the first heat sink 21 and the second heat sink 22. The spacer is formed with a ceramic material that comprises a high thermal conductivity.

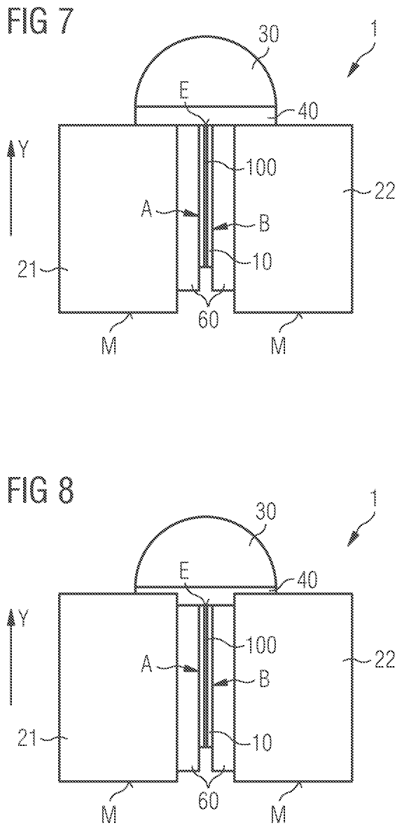

FIG. 7 shows a schematic sectional view of an optoelectronic semiconductor laser component 1 described herein according to a seventh exemplary embodiment. The seventh exemplary embodiment corresponds in essential parts to the sixth exemplary embodiment shown in FIG. 6. In contrast to the sixth exemplary embodiment of an optoelectronic semiconductor laser component 1 shown in FIG. 6, a compensation layer 60 is arranged between the first heat sink 21 and the semiconductor body 10 and between the second heat sink 22 and the semiconductor body 10, respectively. The compensation layer 60 serves to compensate for a different coefficient of thermal expansion between the material of the semiconductor body 10 and the material of the first and second heat sinks 21, 22. For example, the compensation layer 60 is formed with one of the following materials: Copper, Molybdenum, Diamond, Tungsten. Further advantageously, the compensation layers 60 also increase the distance between the mounting surfaces M. The introduction of a first cavity 81 into the first and second heat sinks 21, 22 can thus be advantageously omitted.

FIG. 8 shows a schematic sectional view of an optoelectronic semiconductor laser component 1 described herein according to an eighth exemplary embodiment. The eighth exemplary embodiment corresponds in essential parts to the seventh exemplary embodiment according to FIG. 7. In contrast to the seventh exemplary embodiment from the embodiment of an optoelectronic semiconductor laser component 1 shown in FIG. 7, the eighth exemplary embodiment shown in FIG. 8 comprises a different positioning of the first heat sink 21 and the second heat sink 22 relative to the compensation layers 60 and the semiconductor body 10. The first heat sink 21 and the second heat sink 22 protrude the compensation layers 60 and the semiconductor body 10 at their sides facing the output coupling surface E in the direction of the main emission direction Y, and the output coupling surface E protrudes the compensation layers 60 in the main emission direction Y. The connection layer 40 extends to the semiconductor body 10 and its output coupling surface E and completely covers both the output coupling surface E and the compensation layers 60 in a direction transverse to the main emission direction Y. By having the first and second heat sinks 21, 22 protruding the output coupling surface E in the main emission direction Y, possible damage to the output coupling surface E during assembly of the optical protective element 30 can be advantageously avoided. Furthermore, because the output coupling surface E protrudes the compensation layer 60 in the main emission direction Y, the divergent electromagnetic radiation exiting from the output coupling surface E can leave the optoelectronic semiconductor laser component 1 unobstructed. Particularly advantageously, this results in a structure in which divergent radiation from the output coupling surface E of the coherent electromagnetic radiation can take place unhindered and the output coupling surface E is nevertheless protected from mechanical damage.

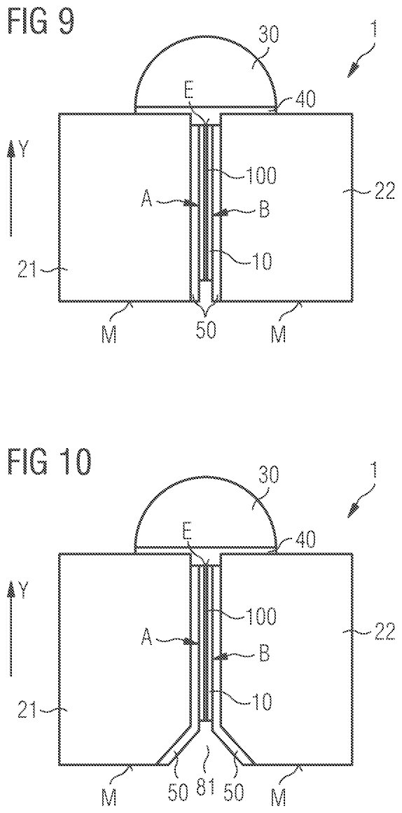

FIG. 9 shows a schematic sectional view of an optoelectronic semiconductor laser component 1 described herein according to a ninth exemplary embodiment. Unlike the previous exemplary embodiments, the exemplary embodiment shown in FIG. 9 comprises a first heat sink 21 and a second heat sink 22 formed with a ceramic, electrically non-conductive material. Further, the first and second heat sinks 21, 22 each comprise a contact structure 50 that is electrically conductive. The heat sinks 21 and 22 are formed with, for example, aluminum nitride, silicon carbide, or direct bonded copper. The contact structures 50 are formed with an electrically highly conductive metal and serve both for electrical connection of the semiconductor body 10 and for dissipation of heat from the semiconductor body 10. The ceramic base bodies of the first and second heat sinks 21, 22 advantageously comprise a very high thermal conductivity and a low coefficient of thermal expansion and can be produced particularly inexpensively.

FIG. 10 shows a schematic sectional view of an optoelectronic semiconductor laser component 1 described herein according to a tenth exemplary embodiment. The tenth exemplary embodiment corresponds in essential parts to the ninth exemplary embodiment according to FIG. 9. In contrast to the ninth exemplary embodiment shown in FIG. 9, the tenth exemplary embodiment comprises a first cavity 81 on the side of the first heat sink 21 and the second heat sink 22 facing the mounting surface M. The contact structures 50 extend directly adjacent to the first and second heat sinks 21 and 22, respectively.

FIG. 11 shows a schematic sectional view of an optoelectronic semiconductor laser component 1 described herein according to an eleventh exemplary embodiment. The eleventh exemplary embodiment corresponds in essential parts to the tenth exemplary embodiment according to FIG. 10. In contrast to the tenth exemplary embodiment shown in FIG. 10, the eleventh exemplary embodiment shown in FIG. 11 comprises a deviating contacting. The electrical contact structures 50 extend to the mounting surfaces M. As a result, a larger area is available for the electrical contacting of the optoelectronic semiconductor laser component 1. This facilitates the electrical contacting of the optoelectronic semiconductor laser component 1.

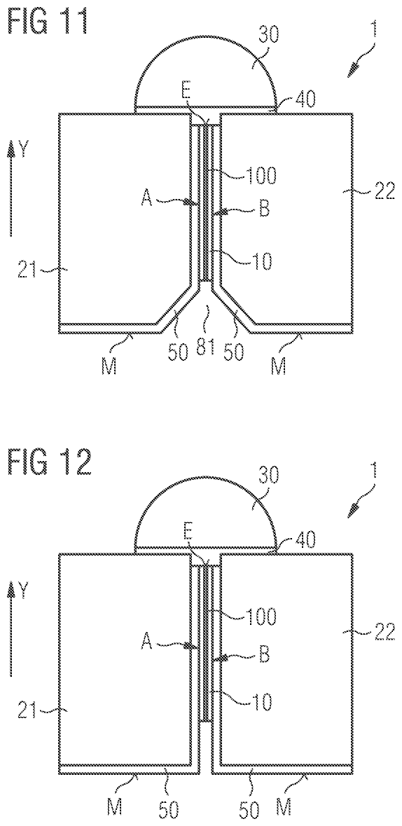

FIG. 12 shows a schematic sectional view of an optoelectronic semiconductor laser component described herein according to a twelfth exemplary embodiment. The twelfth exemplary embodiment corresponds in essential parts to the eleventh exemplary embodiment shown in FIG. 11. In contrast to the eleventh exemplary embodiment shown in FIG. 11, the twelfth exemplary embodiment does not comprise a first cavity 81. The electrical contact metallization 50 extends completely over the mounting surfaces M, resulting in a further increased area for contacting.

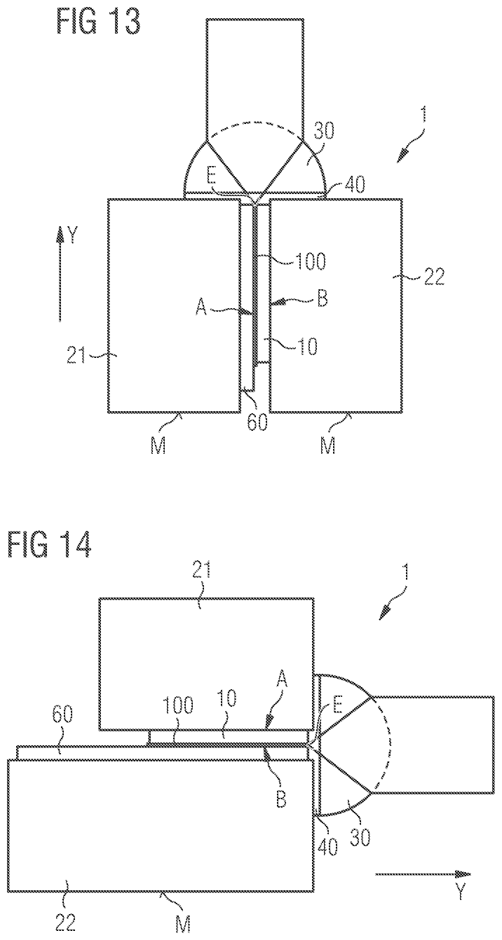

FIG. 13 shows a schematic sectional view of an optoelectronic semiconductor laser component 1 described herein according to a 13th exemplary embodiment. The 13th exemplary embodiment corresponds in essential parts to the eighth exemplary embodiment according to FIG. 8. In contrast to the eighth exemplary embodiment shown in FIG. 8, the 13th exemplary embodiment comprises a compensation layer 60 only on a side of the semiconductor body 10 facing the first heat sink 21. The semiconductor body 10 is directly connected on its second main surface with the second heat sink 22. The connection between the second heat sink 22 and the semiconductor body 10 is made, for example, by means of a soft solder. A soft solder transmits only a small amount of shear forces and can therefore be used to connect bodies with different coefficients of thermal expansion. The connection between the semiconductor body 10 and the compensation layer 60 is made, for example, by means of a brazing alloy, such as a gold/tin alloy.

FIG. 14 shows a schematic sectional view of an optoelectronic semiconductor laser component described herein according to a 14th exemplary embodiment. The 14th exemplary embodiment corresponds in essential parts to the 13th exemplary embodiment according to FIG. 13. The 14th exemplary embodiment shown here differs from the 13th exemplary embodiment shown in FIG. 13 in its mounting and the material selection of the heat sinks. The mounting surface M is parallel to the main emission direction Y and parallel to the first and second main surfaces A and B of the semiconductor body 10. The second heat sink 22 is formed with a ceramic such as AlN or silicon carbide. Thus, the optoelectronic semiconductor laser component 1 shown here is assembled in a side-looker configuration. The electrical contacting and the thermal contacting of the first heat sink 21 is made, for example, by means of a bonding wire.

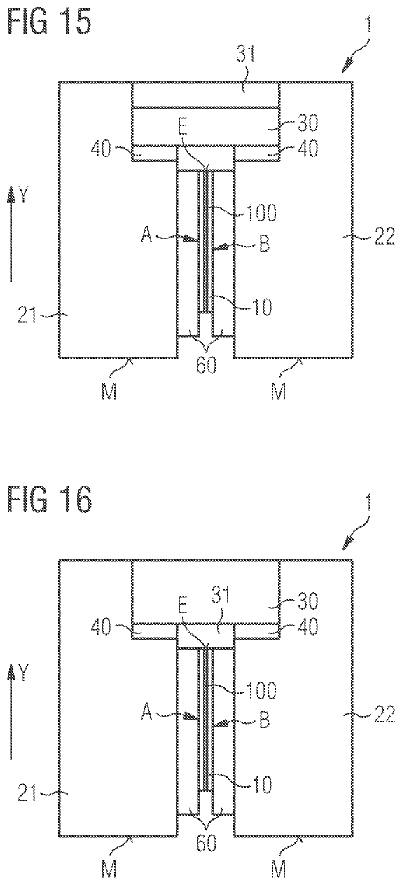

FIGS. 15 to 17 show schematic sectional views of an optoelectronic semiconductor laser component 1 described herein according to a 15th exemplary embodiment, each with different embodiments of an optical protective element 30 and a wavelength conversion layer 31. The 15th exemplary embodiment corresponds in essential parts to the eighth exemplary embodiment according to FIG. 8.

FIG. 15 shows a schematic sectional view of an optoelectronic semiconductor laser component 1 described herein according to the 15th exemplary embodiment. In contrast to the exemplary embodiment shown in FIG. 8, the first and second heat sinks 21 and 22 protrude the semiconductor body 10 in a direction parallel to the main emission direction Y on the side opposite the mounting surface M.

An optical protective element 30 and a wavelength conversion element 31 are disposed downstream of the output coupling surface E in the main emission direction Y. The optical protective element is connected to the first heat sink 21 and the second heat sink 22 by means of a connection layer 40. The optical protective element 30, the wavelength conversion element 31 and the connection layer 40 are surrounded by the first heat sink 21 and the second heat sink 22 in a direction transverse to the main emission direction Y. The output coupling surface (E) is in direct contact with the wavelength conversion element (31). Due to the good thermal connection of the wavelength conversion element 31 to the first and second heat sinks 21, 22, a particularly efficient heat dissipation of the wavelength conversion element 31 can take place. Good heat dissipation may, inter alia, increase the lifetime of the wavelength conversion element 31. The connection layer 40 may be formed by means of a metallic solder joint or by means of an adhesive. The optical protective element 30 is formed with sapphire or glass and is transmissive to electromagnetic radiation generated in the active region 100 during operation.

Alternatively, the optical protective element 30 may be formed of a glass that is applied in liquid form to the first and second heat sinks 21, 22. The liquid glass solidifies in the space between the first and second heat sinks 21, 22 and forms a particularly tight encapsulation of the semiconductor body 10.

The wavelength conversion element 31 comprises a ceramic platelet formed with, for example, Ce:YAG and configured to convert electromagnetic radiation of a first wavelength to electromagnetic radiation of a second wavelength. For example, an optoelectronic semiconductor laser component formed in this manner may be configured to emit electromagnetic radiation with a color impression that is white to an observer.

FIG. 16 shows a schematic sectional view of an optoelectronic semiconductor laser component 1 described herein according to the 15th exemplary embodiment. The wavelength conversion element 31 is arranged between the optical protective element 30 and the semiconductor body 10 in the exemplary embodiment shown in FIG. 16. The optical protective element 30 is connected to the first and second heat sinks 21, 22 by means of a connection layer 40. Due to the good thermal connection of the wavelength conversion element 31 to the first and second heat sinks 21, 22, a particularly efficient heat dissipation of the wavelength conversion element 31 can be performed. The wavelength conversion element 31 is protected from external environmental influences by the optical protective element 30. Furthermore, an improved excitation efficiency can be achieved for the wavelength conversion element 31, since it is located closer to the output coupling surface E, where a higher radiation intensity prevails.

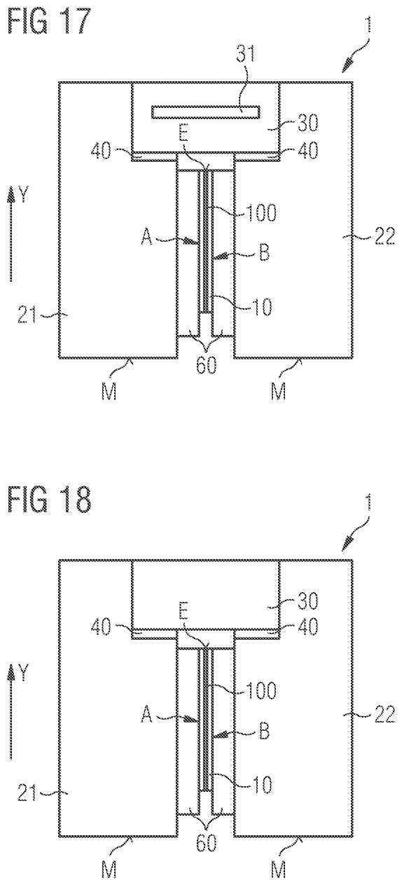

FIG. 17 shows a schematic sectional view of an optoelectronic semiconductor laser component 1 described herein according to the 15th exemplary embodiment. The wavelength conversion element 31 is arranged within the optical protective element 30. The wavelength conversion element 31 is completely surrounded by the optical protective element 30, and is therefore protected from external environmental influences. The optical protective element 30 is connected to the first and second heat sinks 21, 22 by means of a connection layer 40. Due to the good thermal connection of the wavelength conversion element 31 to the first and second heat sinks 21, 22, a particularly efficient heat dissipation of the wavelength conversion element 31 can be achieved.

FIG. 18 shows a schematic sectional view of an optoelectronic semiconductor laser component 1 described herein according to a 16th exemplary embodiment. The 16th exemplary embodiment is substantially the same as the 15th exemplary embodiment shown in FIGS. 15 to 17. Unlike the 15th exemplary embodiment shown in FIGS. 15 to 17, the optical protective element 30 in the exemplary embodiment shown in FIG. 18 is itself formed as a wavelength conversion element. The optical protective element 30 comprises particles of a wavelength conversion material embedded in the material of the optical protective element 30. The optical protective element 30 performs both an optical effect and a protective effect. The optical effect consists of a wavelength-converting effect and the protective effect consists of an encapsulation of the optoelectronic semiconductor laser component 1. Due to the good thermal connection of the optical protective element 30 to the first and second heat sinks 21, 22, a particularly efficient heat dissipation of the wavelength-converting material embedded in the optical protective element 30 can take place. Advantageously, an external wavelength conversion element 31 can thus be dispensed with. The conversion of the coherent electromagnetic radiation can lead to the generation of light in the blue, in the red or green spectral range or also of mixed-colored, in particular white light.

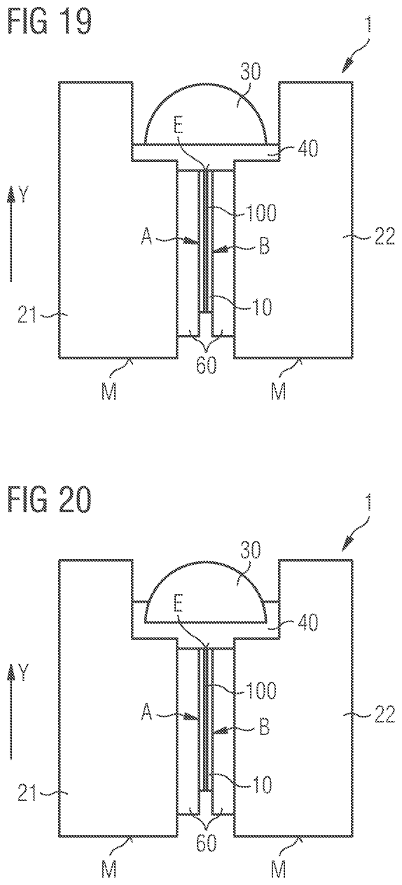

FIGS. 19 to 21 show schematic sectional views of an optoelectronic semiconductor laser component 1 described herein according to a 17th exemplary embodiment, each with different embodiments of a connection layer 40 and an optical protective element 30. The 17th exemplary embodiment corresponds in essential parts to the eighth exemplary embodiment according to FIG. 8. FIG. 19 shows a schematic sectional view of an optoelectronic semiconductor laser component 1 described herein which, in contrast to the eighth exemplary embodiment shown in FIG. 8, comprises a different extension of the first and second heat sinks 21, 22. The first and second heat sinks 21 and 22 protrude both the protective layer 40 and the optical protective element 30 in a direction parallel to the main emission direction Y. The first and second heat sinks 21, 22 thus form a lateral guide for the optical protective element 30 and the connection layer 40. Advantageously, this results in an adjusting effect of the first and second heat sinks 21, 22 when applying the connection layer 40 and adjusting the optical protective element 30. Further advantageously, the optical protective element 30 is better protected against mechanical destruction. The connection layer 40 extends from the first heat sink 21 to the second heat sink 22 and completely covers the output coupling surface E of the semiconductor body 10. The optical protective element 30 is arranged directly on the connection layer 40.

FIG. 20 shows a schematic sectional view of an optoelectronic semiconductor laser component described herein according to the 17th exemplary embodiment, which comprises a different extension of the connection layer 40 in contrast to the exemplary embodiment shown in FIG. 19. The connection layer 40 is designed in such a way that the optical protective element 30 is also enclosed by the connection layer 40 on its side surfaces, which are aligned transversely to the main emission direction Y. This advantageously results in increased stability of the optical protective element 30 in the connection layer 40. If the optical protective element 30 comprises the shape of a lens, exact adjustment of the optical protective element 30 in a direction transverse to the main emission direction Y with respect to the output coupling surface E is necessary. An exact adjustment is advantageously simple if the heat sinks 21 and 22 already provide a lateral boundary in which the optical protective element 30 can be arranged.

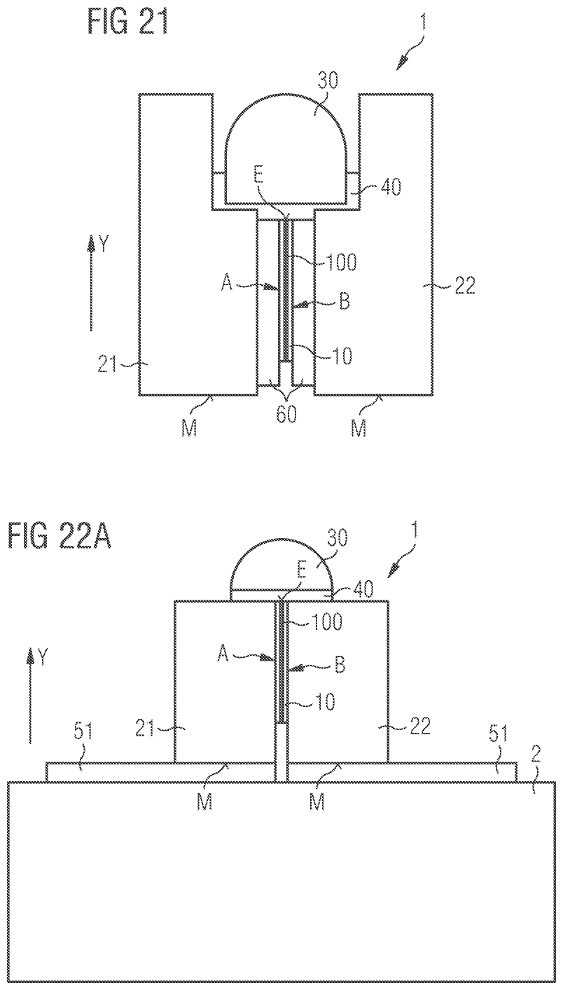

FIG. 21 shows a schematic sectional view of an optoelectronic semiconductor laser component 1 described here according to the 17th exemplary embodiment, which in contrast to the exemplary embodiment shown in FIG. 20 shows an optical protective element 30 in the form of a lens with a larger extension. The optical protective element 30 in the exemplary embodiment shown in FIG. 21 can advantageously be connected to the first heat sink 21 and the second heat sink 22 in a mechanically particularly stable manner by means of the connection layer 40 which is formed higher in the main emission direction Y.

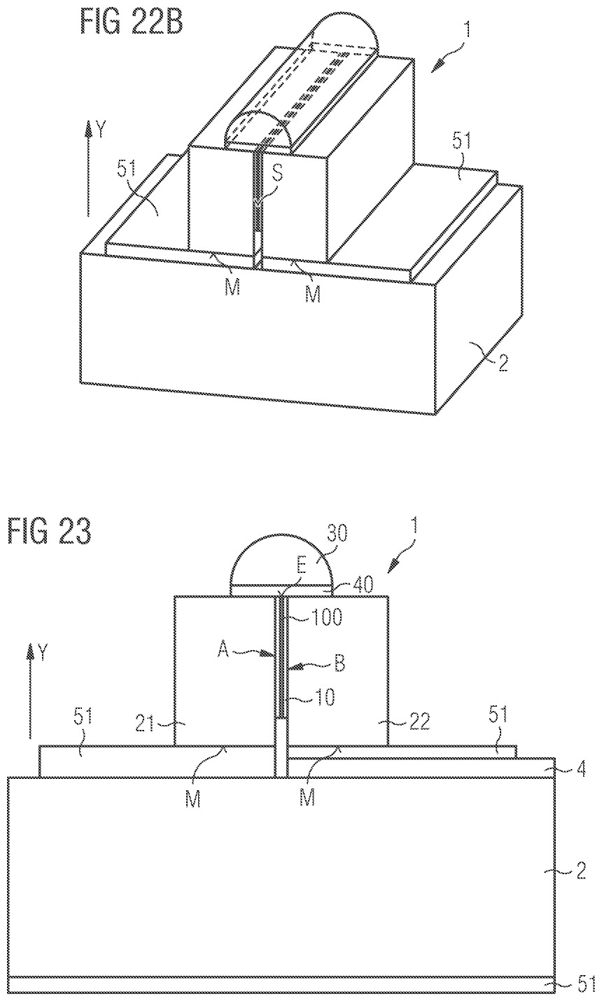

FIGS. 22A and 22B show schematic representations of an optoelectronic semiconductor laser component 1 described herein according to an 18th exemplary embodiment. The 18th exemplary embodiment corresponds in essential parts to the fourth exemplary embodiment according to FIGS. 4A and 4B. FIG. 22A shows a sectional view of an optoelectronic semiconductor laser component 1 arranged on a substrate 2 by means of electrical contact regions 51. The optoelectronic semiconductor laser component 1 is arranged with the mounting surfaces M on the contact regions 51. The main emission direction Y is in the direction of a normal vector of the substrate 2, resulting in a so-called top-looker design of the optoelectronic semiconductor laser component 1. The substrate 2 is a ceramic with good thermal conductivity, which is provided for efficient heat dissipation from the optoelectronic semiconductor laser component 1. Further electrical contacting of the contact regions 51 can be realized, for example, via a wire bond to the contact regions 51.

FIG. 22B shows a perspective view of the optoelectronic semiconductor laser component 1 shown in FIG. 22A. In the perspective view, a side surface S of the semiconductor body 10 is shown. The side surface S extends transversely to the first and second main surfaces of the semiconductor body 10. The side surface S is not covered by the first heat sink 21 and the second heat sink 22.

FIGS. 23 to 25 show schematic sectional views of an optoelectronic semiconductor laser component 1 described herein according to a 19th exemplary embodiment, each with different embodiments of an electrical contact. The 19th exemplary embodiment corresponds in essential parts to the 18th exemplary embodiment according to FIGS. 22A and 22B. FIG. 23 shows a schematic sectional view of an optoelectronic semiconductor laser component 1 which, in contrast to the exemplary embodiment shown in FIG. 22A, is arranged on an electrically conductive substrate 2. For example, the substrate is formed with copper. The substrate 2 comprises both a high electrical and a high thermal conductivity and is used for electrical contacting and for dissipating waste heat from the optoelectronic semiconductor laser component 1. To avoid an electrical short circuit between the first heat sink 21 and the second heat sink 22, an insulating layer 4 is arranged between one of the contact regions 51.

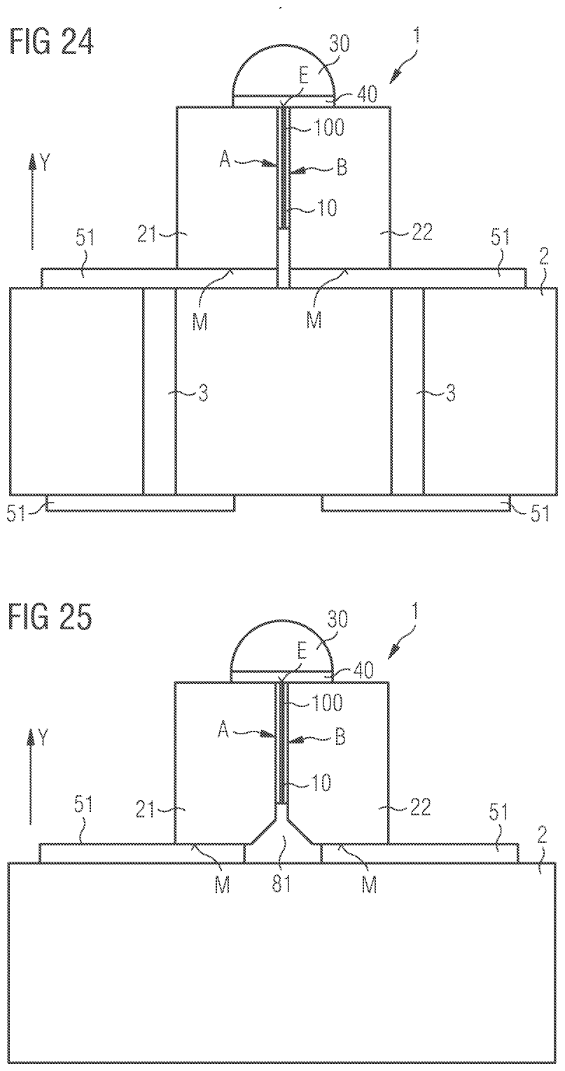

FIG. 24 shows a schematic sectional view of an optoelectronic semiconductor laser component described here according to the 19th exemplary embodiment, which comprises different contacting in contrast to the exemplary embodiment shown in FIG. 23. The optoelectronic semiconductor laser component 1 is arranged on an electrically non-conductive substrate 2, which is formed with a ceramic, for example. Via 3 and contact regions 51 are used for contacting. Contacting can thus advantageously take place on a back side and can be implemented in a particularly space-saving manner.

FIG. 25 shows a schematic sectional view of an optoelectronic semiconductor laser component 1 described here according to the 19th exemplary embodiment, which in contrast to the exemplary embodiment shown in FIG. 24 comprises no vias. The substrate 2 on which the optoelectronic semiconductor laser component 1 is arranged is an electrically non-conductive ceramic substrate. On the substrate 2 there are contact regions 51 which, due to a first cavity 81 of the optoelectronic semiconductor laser component 1, comprise a sufficiently high spacing to enable simple soldering contacting of the mounting surfaces M.

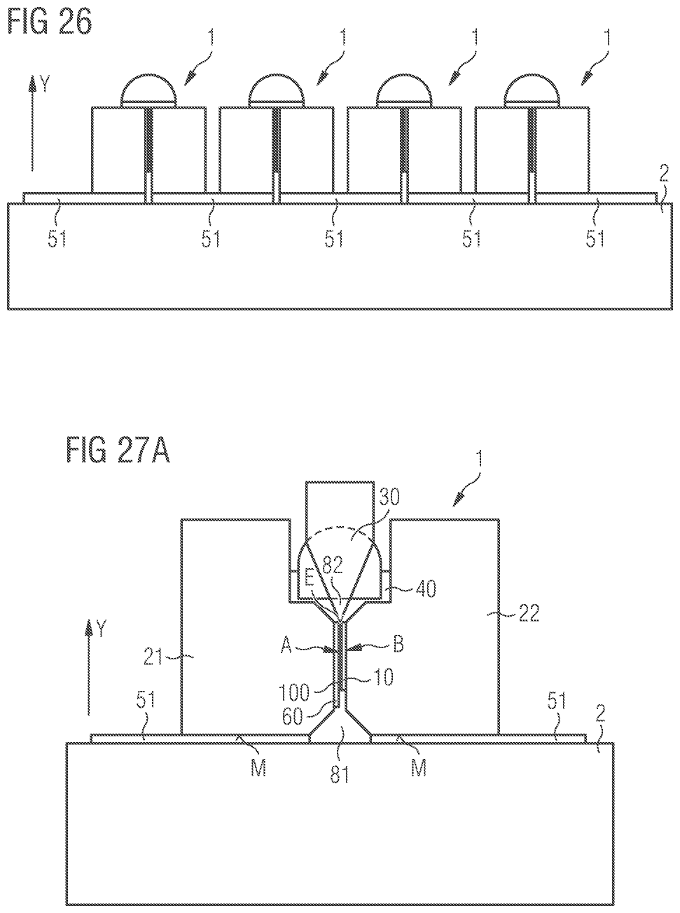

FIG. 26 shows a schematic sectional view of optoelectronic semiconductor laser components 1 described herein according to a 20th exemplary embodiment. The 20th exemplary embodiment is substantially the same as the 18th exemplary embodiment shown in FIGS. 22A and 22B. A plurality of optoelectronic semiconductor laser components 1 are arranged side by side on a common substrate 2. The optoelectronic semiconductor laser components 1 all comprise an emission direction in a main emission direction Y, which is parallel to each other. Contact is made via contact regions 51 on a non-conductive ceramic substrate 2. Each optoelectronic semiconductor component 1 shown here comprises a plurality of active regions 100 and is thus a laser bar. Thus, a two-dimensional matrix of light emitting regions is formed. Heat is dissipated from the optoelectronic semiconductor laser components 1 by means of the two-sided, first and second heat sinks 21, 22.

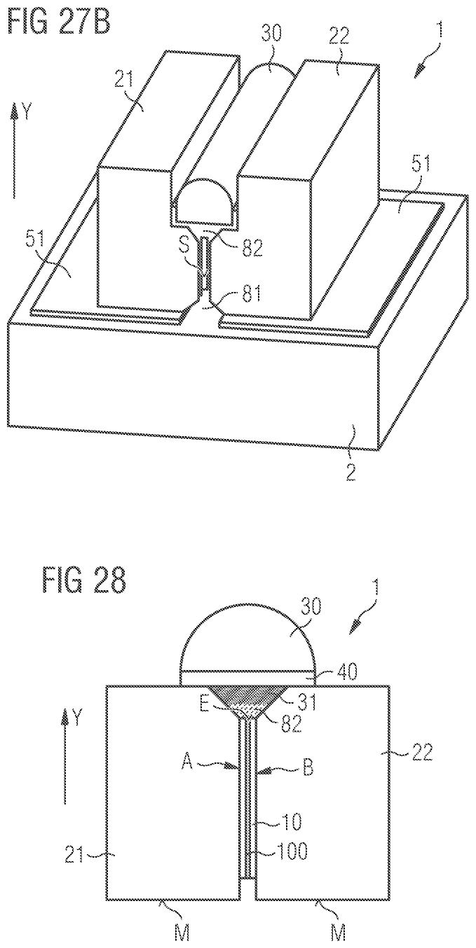

FIGS. 27A and 27B show schematic representations of an optoelectronic semiconductor laser component described herein according to an exemplary embodiment 21. The 21st exemplary embodiment corresponds in essential parts to the 17th exemplary embodiment shown in FIG. 21. FIG. 27A shows a schematic sectional view of an optoelectronic semiconductor laser component 1 which, in contrast to the 17th exemplary embodiment shown in FIG. 21, comprises a first cavity 81 and a second cavity 82, and only a compensation layer 60 is arranged between the first and second heat sinks 21, 22 and the semiconductor body 10. The second cavity 82 is formed on the sides of the first and second heat sinks 21, 22 opposite to the mounting surfaces M. The connection layer 40 is arranged in the second cavity 82, and the optical protective element 30 is arranged downstream of the second cavity 82. Advantageously, the second cavity 82 allows unobstructed emission of radiation which exits from the output coupling surface E and comprises a divergence. Advantageously, the flank angle of the second cavity 82 is adapted to the divergence angle of the electromagnetic radiation exiting the output coupling surface E. The first cavity 81 is opposite the second cavity 82 and advantageously prevents a solder short circuit between the first and the second heat sink 21, 22 when applied to the contact regions 51, which are arranged on the substrate 2.

FIG. 27B shows a perspective view of the optoelectronic semiconductor laser component 1 shown in FIG. 27A. In the perspective view, a side surface S of the semiconductor body 10 is shown. The side surface S extends transversely to the first and second main surfaces of the semiconductor body 10. The side surface S is not covered by the first heat sink 21 and the second heat sink 22.

FIG. 28 shows a schematic sectional view of an optoelectronic semiconductor laser component 1 described herein according to a 22nd exemplary embodiment. The 22nd exemplary embodiment corresponds in essential parts to the fourth exemplary embodiment according to FIGS. 4A and 4B. Unlike the fourth exemplary embodiment shown in FIG. 4A, the 22nd exemplary embodiment comprises a second cavity 82 on the sides of the first heat sink 21 and the second heat sink 22 opposite to the mounting surfaces M. The second cavity 82 is filled with a wavelength conversion material 31 and is located downstream of the output coupling surface E. The output coupling surface (E) is in direct contact with the wavelength conversion material (31). Downstream of the wavelength conversion element 31 is a connection layer 40 and the optical protective element 30. The connection layer 40 completely covers the wavelength conversion element 31 and connects the first and second heat sinks 21, 22 to one another in a materially bonded manner. Particularly advantageously, this embodiment results in a very good cooling of the wavelength conversion material 31. A good cooling of the wavelength conversion material 31 advantageously increases the lifetime and the wavelength stability of the wavelength conversion material 31. The wavelength conversion material 31 comprises a continuous course of the density of the wavelength conversion material. For example, starting from the output coupling surface E in the direction of the main emission direction Y, the density continuously increases with increasing distance from the output coupling surface E. Thus, a uniform excitation of the wavelength conversion material can be achieved. The flank angle of the second cavity 82 is adapted to the far-field divergence of the optoelectronic semiconductor laser component 1. The wavelength conversion element 31 can, for example, effect a conversion of the radiation exiting the output coupling surface E into a green, a red, a blue or even far-infrared radiation.

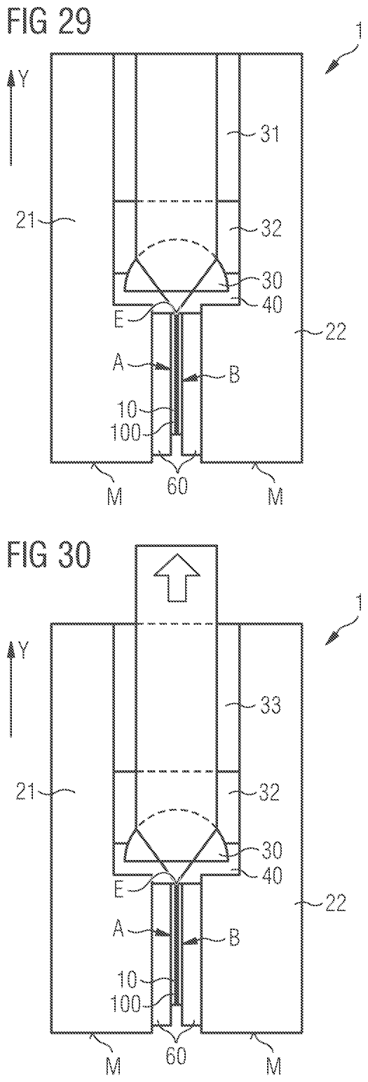

FIG. 29 shows a schematic sectional view of an optoelectronic semiconductor laser component 1 described herein according to a 23rd exemplary embodiment. The 23rd exemplary embodiment corresponds in essential parts to the 17th exemplary embodiment according to FIG. 20. In contrast to the exemplary embodiment shown in FIG. 20, the exemplary embodiment shown in FIG. 29 comprises a larger extension of the first and second heat sinks 21, 22. The optical protective element 30 is followed by an optical filter element 32, which in turn is followed by a wavelength conversion element 31. The first and second heat sinks 21 and 22 are formed such that they project beyond the optical protective element 30 in the main emission direction Y. The optical filter element 32 and the wavelength conversion element 31 are surrounded by the first and second heat sinks 21, 22 transverse to the main emission direction. The optical filter element 32 comprises a dichromate that reflects electromagnetic radiation from the wavelength conversion element 31 but is transmissive to electromagnetic radiation from the output coupling region E. Thus, a particularly efficient conversion of the electromagnetic radiation exiting from the output coupling surface E can take place. Furthermore, a particularly good cooling of the wavelength conversion material 31 takes place due to the direct contact with the first heat sink 21 and the second heat sink 22. The side surfaces of the first heat sink 21 and the second heat sink 22 adjacent to the wavelength conversion material 31 are coated with a highly reflective material. For example, the side surfaces of the first and second heat sinks 21 and 22 are coated with silver in this region.

FIG. 30 shows a schematic sectional view of an optoelectronic semiconductor laser component 1 described herein according to a 24th exemplary embodiment. In contrast to the exemplary embodiment shown in FIG. 29, the wavelength conversion material 31 is replaced by an optical crystal 33. The optical crystal 33 is, for example, a titanium sapphire crystal which can be excited to emit coherent radiation. Thus, a microchip laser can be realized in a particularly simple manner, comprising a simple adjustment and a robust resonator.

1. An optoelectronic semiconductor laser component comprising:
a semiconductor body with
a first main surface,
a second main surface,
at least one active region formed between the first main surface and the second main surface and intended to emit coherent electromagnetic radiation, and
an output coupling surface extending from the first main surface to the second main surface and through which at least part of the electromagnetic radiation is coupled out,
a first heat sink arranged on the first main surface and a second heat sink arranged on the second main surface; and
an optical protective element arranged downstream of the output coupling surface, for which the first heat sink and/or the second heat sink form a carrier, wherein
the optical protective element or a wavelength conversion element or a connection layer being in direct contact with the output coupling surface,
the output coupling takes place in a main emission direction,
electrical contacting of the semiconductor body takes place by means of the first heat sink and the second heat sink, and
the first heat sink and/or the second heat sink comprise mounting surfaces on a side opposite the output coupling surface, on a side opposite the first main surface and/or on a side opposite the second main surface.

2. The optoelectronic semiconductor laser component according to claim 1, in which the semiconductor body comprises a plurality of active regions which are arranged laterally spaced apart, wherein the lateral spacing of the active regions from one another is the same, or wherein the lateral spacing of the active regions from one another increases outwardly from the center of the semiconductor body, or wherein the lateral spacing of the active regions from one another decreases outwardly from the center of the semiconductor body.

3. The optoelectronic semiconductor laser component according to claim 1, in which the optical protective element is in direct contact with the first heat sink and/or the second heat sink.

4. The optoelectronic semiconductor laser component according to claim 1, wherein the optical protective element is formed with a dielectric material.

5. The optoelectronic semiconductor laser component according to claim 1, wherein the optical protective element is formed with at least one of the following materials: SiO₂, Al₂O₃, ZrO₂, HfO₂, TiO₂, Ta₂O₅, Si₃N₄, Nb₂O₅, Y₂O₃, Ho₂O₃, CeO₂, Lu₂O₃, V₂O₅, HfZrO, MgO, TaC, ZnO, CuO, In₂O₃, Yb₂O₃, Sm₂O₃, Nd₂O₃, Sc₂O₃, B₂O₃, Er₂O₃, Dy₂O₃, Tm₂O₃, SrTiO₃, BaTiO₃, PbTiO₃, PbZrO₃, Ga₂O₃, HfAlO, HfTaO, SiC, DLC, Diamant, AlN, AlGaN.

6. The optoelectronic semiconductor laser component according to claim 1, in which the optical protective element is materially connected to the first heat sink and/or the second heat sink by means of a connection layer.

7. The optoelectronic semiconductor laser component according to claim 6, in which the connection layer completely covers the output coupling surface.

8. The optoelectronic semiconductor laser component according to claim 1, wherein the optical protective element comprises the shape of a lens.

9. The optoelectronic semiconductor laser component according to claim 8, in which the optical protective element is provided for collimating electromagnetic radiation exiting from the output coupling surface during operation of the optoelectronic semiconductor laser component in at least one axis transverse to the main emission direction.

10. The optoelectronic semiconductor laser component according to claim 1, wherein the optical protective element comprises a wavelength conversion element.

11. The optoelectronic semiconductor laser component according to claim 1, wherein the first heat sink and/or the second heat sink is formed with at least one of the following materials: Cu, Cu-steel, CuW, Au, CuMo, Cu-diamond, AlN, SiC, BN, DBC.

12. The optoelectronic semiconductor laser component according to claim 1, in which the first heat sink and/or the wide heat sink comprise an electrically conductive contact structure.

13. The optoelectronic semiconductor laser component according to claim 1, in which the first heat sink and the second heat sink project beyond the optical protective element in a direction parallel to the main emission direction.

14. The optoelectronic semiconductor laser component according to claim 1, in which the semiconductor body comprises a side surface extending transversely or perpendicularly to the output coupling surface, which is not covered by the first heat sink or the second heat sink.

15. The optoelectronic semiconductor laser component according to claim 1, in which a compensation layer is arranged between the semiconductor body and the first heat sink and/or between the semiconductor body and the second heat sink.

16. The optoelectronic semiconductor laser component according to claim 15, in which the first heat sink and the second heat sink project beyond the at least one compensation layer in the main emission direction, and in which the output coupling surface projects beyond the at least one compensation layer in the main emission direction.

17. The optoelectronic semiconductor laser component according to claim 16, wherein the at least one compensation layer is formed with at least one of Cu, Mo, diamond, W, DLC, AlN and SiC.

18. A method for producing an optoelectronic semiconductor laser component comprising:
providing a semiconductor body, with
a first main surface,
a second main surface,
at least one active region formed between the first main surface and the second main surface and intended to emit coherent electromagnetic radiation, and
an output coupling surface extending from the first main surface to the second main surface, through which at least a part of the electromagnetic radiation is coupled out,
arranging a first heat sink on the first main surface and a second heat sink on the second main surface; and
arranging an optical protective element on the first heat sink and the second heat sink, such that the optical protective element is arranged downstream of the output coupling surface and the optical protective element or a wavelength conversion element or a connection layer is in direct contact with the output coupling surface.

19. The method for producing an optoelectronic semiconductor laser component according to claim 18, wherein the optical protective element is formed with a dielectric material and is produced by one or a combination of the following methods: ALD, CVD, IBD, IP, sputtering, vapor deposition, MVD.

20. The method for producing an optoelectronic semiconductor laser component according to claim 18, wherein the optical protective element is formed with a glass and arranged by means of reflow in a second cavity of the first heat sink and the second heat sink.
